(19) United States
(12) Patent Application Publication
(10) Pub. No.: US 2026/0181818 A1
(43) Pub. Date: Jun. 25, 2026

(54) IMPELLER DESIGNS FOR IMPROVED LAPTOP COOLING AND PERFORMANCE

(71) Applicant: Intel Corporation, Santa Clara, CA (US)

(72) Inventors: Amit Kumar, Bangalore (IN); Rachit Garg, Bangalore (IN); Arnab Sen, Whitefield (IN); Prasanna Pichumani, Bangalore (IN); Srinivasarao Konakalla, Bangalore (IN); Prakash Kurma Raju, Bangalore (IN); Jeff Ku, Taipei City (TW); Alonso Rodriguez Chacon, Guacima (CR)

(73) Assignee: Intel Corporation, Santa Clara, CA (US)

(21) Appl. No.: 18/990,664

(22) Filed: Dec. 20, 2024

(51) Int. Cl. H05K 7/20; F04D 29/28

(52) U.S. Cl. CPC H05K 7/20172; F04D 29/281

(57) ABSTRACT

In one embodiment, a blower apparatus includes an impeller comprising a plurality of blades extending from a central hub and at least one annular disc coupled to the plurality of blades. In some embodiments, the each impeller blade comprises a body portion and surfaces extending approximately orthogonally from the body portion of the blade (e.g., in opposite directions from the body portion).

### BACKGROUND

Cooling fans in mobile devices, e.g., laptop computers, are a critical thermal design component to prevent overheating of the circuitry of the device, e.g., one or more processors of the device. Cooling requirements continue to become more stringent as the devices both consume more power and are reduced in size. In addition, users demand quieter operation of such devices as well.

### BRIEF DESCRIPTION OF THE DRAWINGS

FIGS. 1A-1B illustrate an example blower apparatus with a modified impeller design in accordance with embodiments of the present disclosure.

FIG. 2 illustrates a perspective view of an example modified impeller design in accordance with embodiments of the present disclosure.

FIG. 3 illustrates an exploded view of an example modified impeller design in accordance with embodiments of the present disclosure.

FIG. 4 illustrates an exploded view of another example modified impeller design in accordance with embodiments of the present disclosure.

FIGS. 5A-5E illustrate example experimental data showing the benefits of impeller designs of the present disclosure.

FIGS. 6A-6C illustrate another example modified impeller design in accordance with embodiments of the present disclosure.

FIGS. 7A-7B illustrate yet another example modified impeller design in accordance with embodiments of the present disclosure.

FIG. 8 illustrates a computing device incorporating a blower apparatus of the present disclosure.

FIG. 9 illustrates a simplified block diagram of a computing device in which aspects of the present disclosure may be incorporated.

FIG. 10 illustrates an example computing device in which aspects of the present disclosure may be incorporated.

FIG. 11 illustrates an example block diagram of a computing device in which aspects of the present disclosure may be incorporated.

FIG. 12 is a block diagram of computing device components which may be included in a mobile computing device incorporating aspects of the present disclosure.

FIG. 13 is a block diagram of an example processor unit to execute computer-executable instructions.

### DETAILED DESCRIPTION

In the following description, specific details are set forth, but aspects of the technologies described herein may be practiced without these specific details. Well-known circuits, structures, and techniques have not been shown in detail to avoid obscuring an understanding of this description. “An embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Terms modified by the word “substantially” include arrangements, orientations, spacings, or positions that vary slightly from the meaning of the unmodified term. For example, description of a lid of a mobile computing device that can rotate to substantially 360 degrees with respect to a base of the mobile computing includes lids that can rotate to within several degrees of 360 degrees with respect to a device base.

The description may use the phrases “in an embodiment,” “in embodiments,” “in some embodiments,” and/or “in various embodiments,” each of which may refer to one or more of the same or different embodiments. Furthermore, the terms “comprising,” “including,” “having,” and the like, as used with respect to aspects of the present disclosure, are synonymous.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims. While aspects of the present disclosure may be used in any suitable type of computing device, the examples below describe example mobile computing devices/environments in which aspects of the present disclosure can be implemented.

Aspects of the present disclosure relate to impeller designs that improve laptop (or other mobile device) performance by reducing fan-generated noise, resulting in better overall IsoAcoustic P-Q curves. For example, certain embodiments herein include a thin film annular disc on top and/or bottom sides of the impeller blades, resulting in a surface that is about or approximately orthogonal (e.g., within +/−10° of orthogonal) to the impeller blades. These designs can provide noise reduction as compared with fan designs that do not include such discs. The annular disc may be coupled to the impeller blades (e.g., on one or both sides), integrated with the impeller blades (e.g., on one or both sides), or a combination thereof (e.g., integrated on one side and coupled to another side). Other embodiments may include impeller blades with integrated end portions that provide similar noise reduction effects.

In current designs, there are various sources of aeroacoustics noise. One of the dominant noise generation mechanisms is when vortices are shed from impeller blade tips or edges. This noise generation mechanism contributes to broadband noise as it's generally spread over a large sound frequency interval. In addition, when the transient nature of flow leaving the impeller from the top and bottom edges interacts with the fan casing, additional noise can be generated. In addition, due to the divergent nature of the blades, flow separation also generally takes place, leading to additional noise.

In aspects of the present disclosure, however, thin film annular discs coupled to/integrated with top or bottom sides of the impeller blades can inhibit/reduce flow separation, and thus inhibit vortex shedding from occurring at the blade top and bottom surfaces. This is because the discs may reduce edges close to tip of the impeller blades and thus inhibit the generation of noise associated with vortex shedding from blade edges. There may also be a reduction in the interactions between the fan casing and the flow leaving the impeller. In addition, the discs can increase viscous effects, which can further reduce turbulence. Each of these can provide an overall reduction in the noise observed by a user. The discs can be relatively thin compared with the impeller and overall fan casing design, so the overall increase in the impeller size may be negligible. In some embodiments, the width of the top and bottom discs can be the same, while in other embodiments, the discs on the top and bottom may be different.

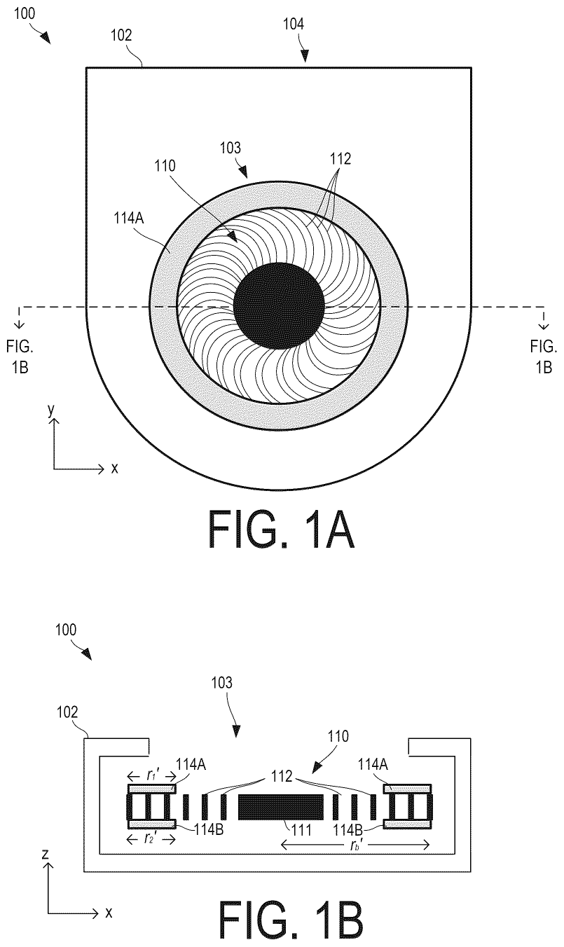

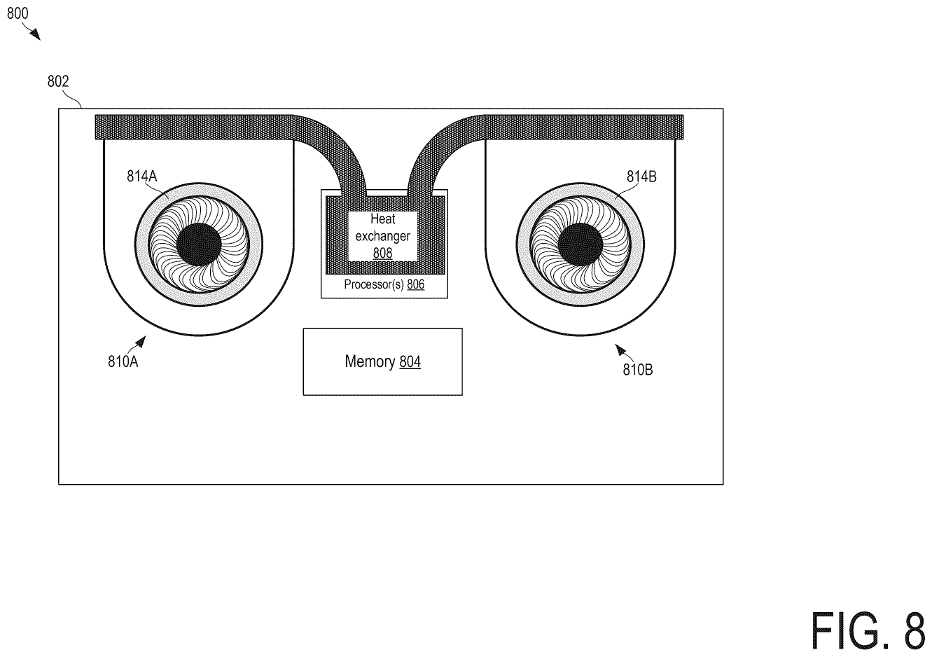

FIGS. 1A-1B illustrate an example blower apparatus 100 with a modified impeller design in accordance with embodiments of the present disclosure. The example blower apparatus 100 may be used, in certain cases, as a cooling fan in a computing device, e.g., the one shown in FIG. 8, which may be embodied as a laptop computing device or other type of mobile device.

The example blower apparatus 100 includes a housing 102 with an impeller 110 therein. The blower apparatus 100 shown is implemented with a centrifugal fan design, whereby the impeller 110 includes a central hub 111 and blades 112 extending from the hub 111. The housing 102 includes an inlet opening 103 on a top side of the housing and an outlet opening 104 on a side of the housing as shown. During operation, the blades 112 rotate, causing air to flow into the housing 102 through the inlet opening 103 and then out of the housing 102 through the outlet opening 104.

The blower apparatus 100 includes annular-shaped discs 114A, 114B coupled to the blades 112 of the impeller 110, as shown. More particularly, a first disc 114A is coupled to a top side of the impeller blades 112 and a second disc 114B coupled to a bottom side of the impeller blades 112. The discs 114 are generally flat, and are coupled to the impeller blades such that they are about or approximately orthogonal to the blades 112 (e.g., with 10° of orthogonal). In some embodiments, the discs 114 may be coupled to the blades, e.g., via an adhesive, while in some embodiments, the discs 114 may be integrated with or part of the blades. In some embodiments, one of the discs is coupled to the blades while another disc is integrated with the blades.

The discs may be the same size, thickness, etc. as one another, or may have a different size, thickness, or other dimension. For example, in some embodiments, the thickness (z-height) of the discs 114 may differ from one another and/or the annular/radial dimensional size (in the x- and y-dimensions, rₓ′ shown in FIG. 1B) may differ from one another. For example, the radial dimension r₁′ of the disc 114A may be the same as the radial dimension r₂′ of the disc 114B in certain embodiments, while the radial dimensions may differ in other embodiments. The discs 114 may be disposed over 1-50% (e.g., between 10-35%) of the radial dimension of the blades 112 (r_{b}′) in certain embodiments. Although the example shown includes discs 114 on both top and bottom sides of the impeller blades 112, other embodiments may include only one of the discs 114A or 114B. The discs 114 may be made of any suitable, generally lightweight material, e.g., acrylic, polyethylene terephthalate (PET) (e.g., mylar), polycarbonate, liquid crystal polymer (LCP), carbon fiber reinforced polymer, glass, metal (e.g., titanium), etc.

In some embodiments, the thickness of the discs may be about or approximately between 5% to 35% of the impeller height (at the tip of the impeller), so that they may have a negligible effect on the overall z-height of the impeller and overall blower apparatus. In addition, the width of the discs in the radial direction may be about or approximately between 1-50% of the impeller radius, and the width of the ring may vary azimuthally with respect to the impeller's axis of rotation. Furthermore, although illustrated as including one disc on each side of the impeller 110, some embodiments may include multiple discs on one or both sides of the impeller. That is, some embodiments may include a first disc at a first radial location of the impeller and a second disc at a second radial location different from the first, with both discs on the same side of the impeller (e.g., top side).

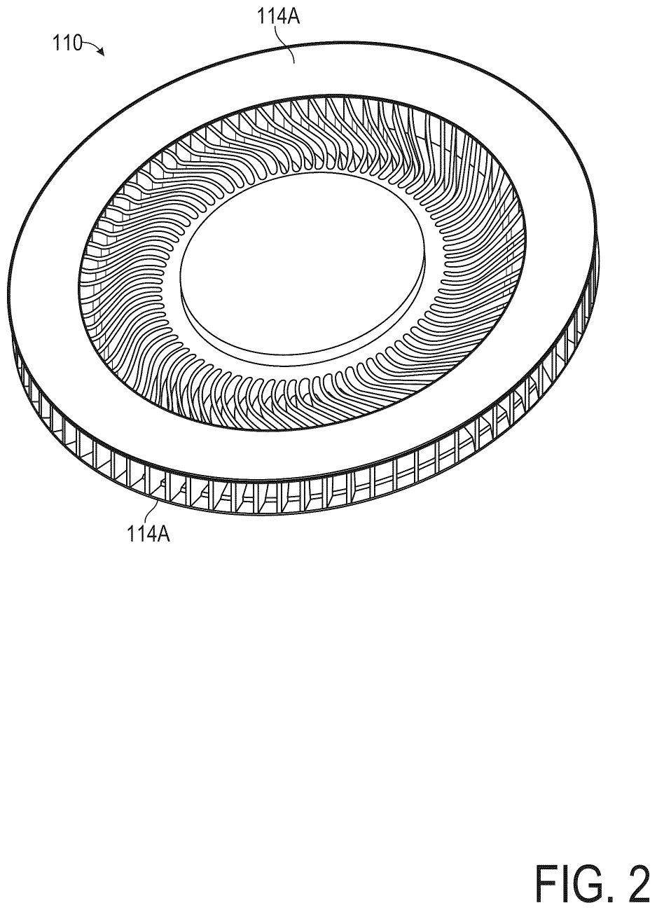

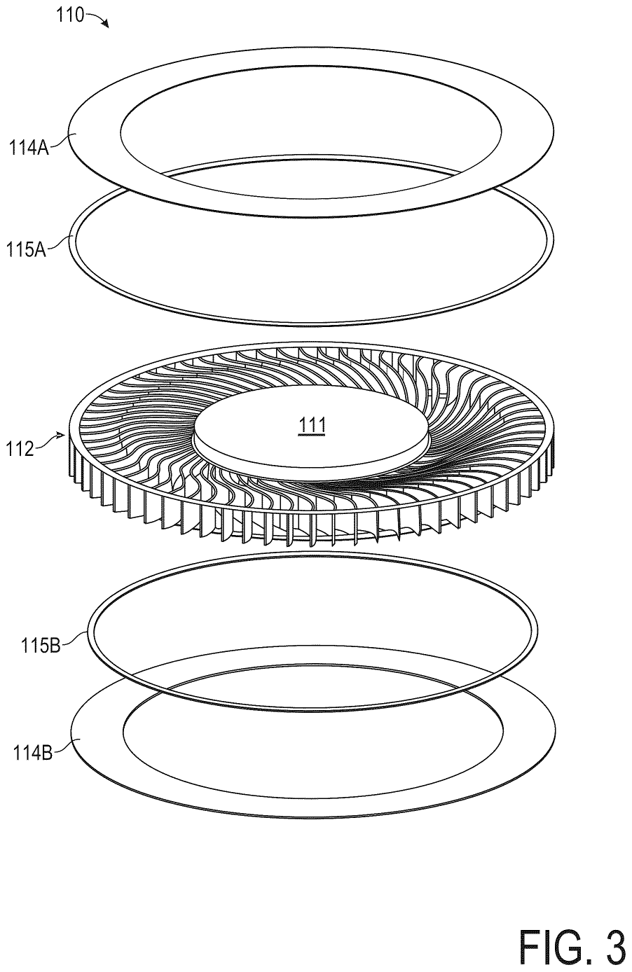

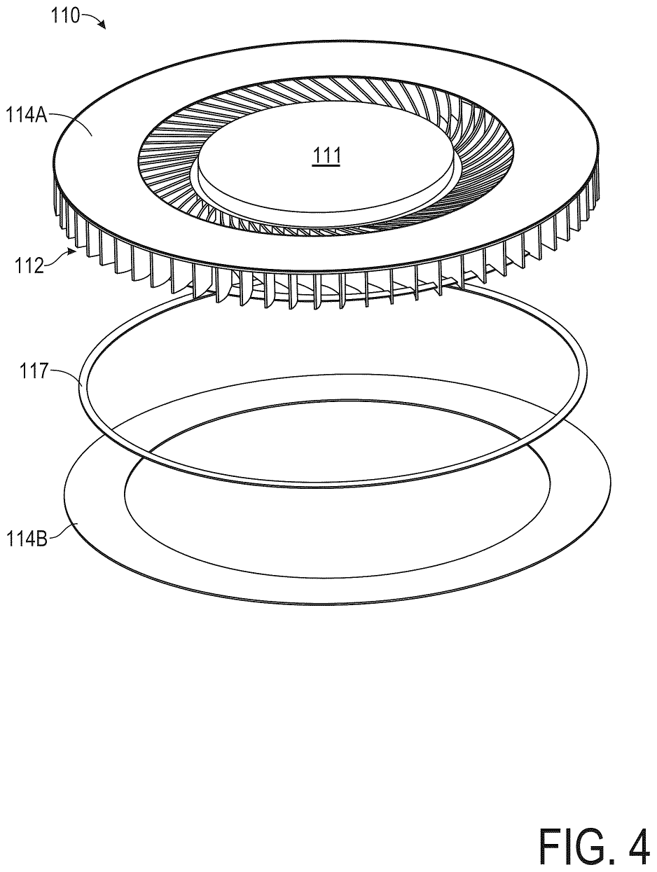

FIGS. 2-4 illustrate example views of modified impeller designs in accordance with embodiments of the present disclosure. In particular, FIG. 2 illustrates a perspective view of the impeller 110 with the discs 114A, 114B coupled thereto; FIG. 3 illustrates an exploded view of an example modified impeller design with discs 114A, 114B adhered to the blades 112 (via adhesive rings 115A, 115B, respectively); and FIG. 4 illustrates an exploded view of another example modified impeller design with the disc 114A being integrated with one side of the blades 112 and disc 114B being adhered to the opposite side of the blades 112 (via adhesive rings 117).

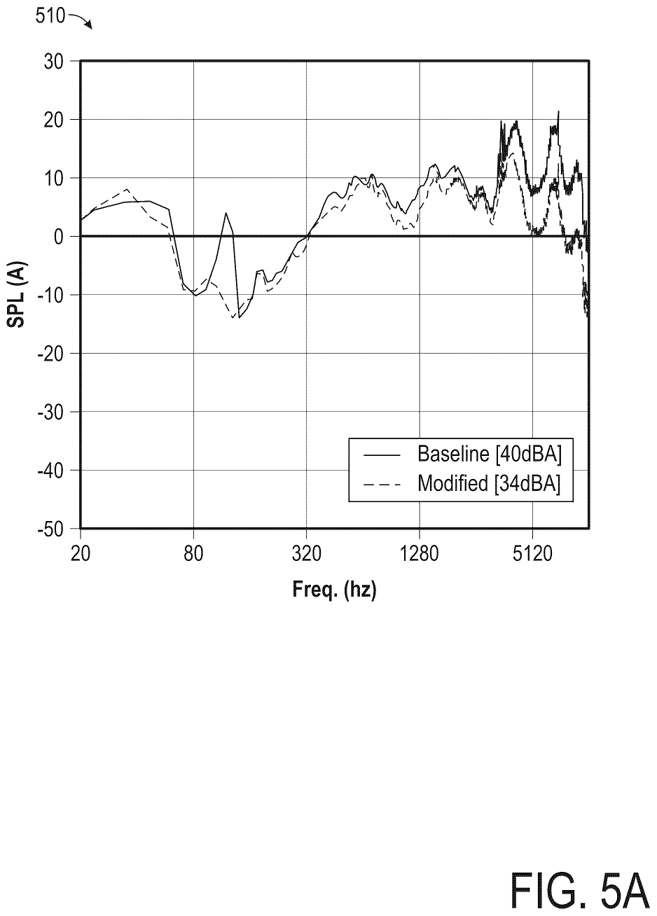

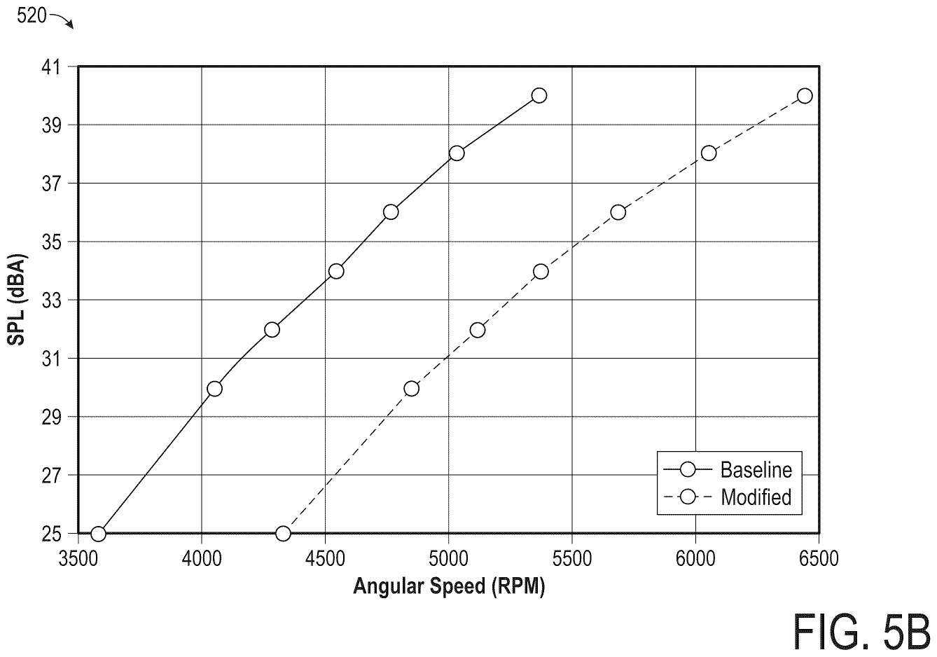

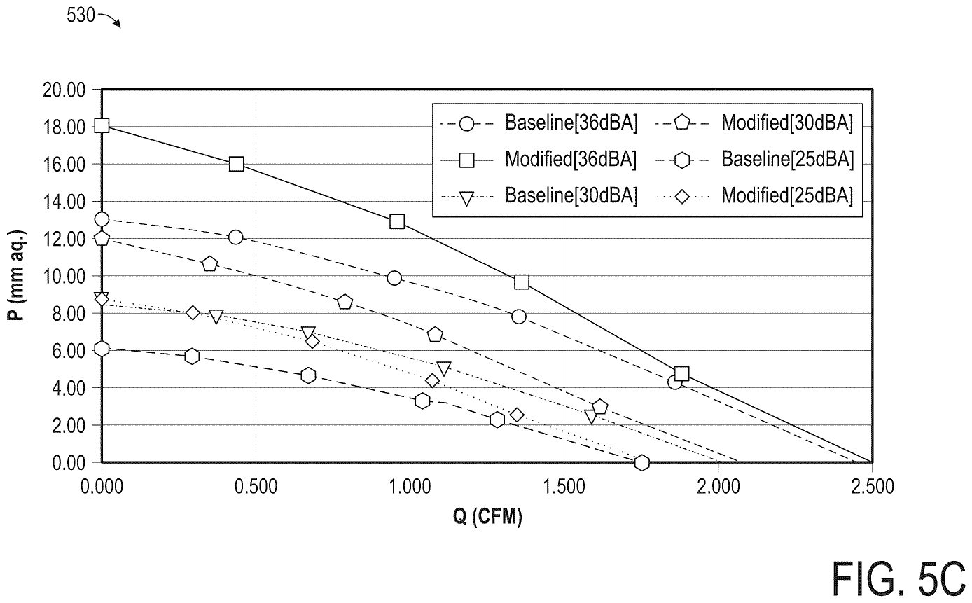

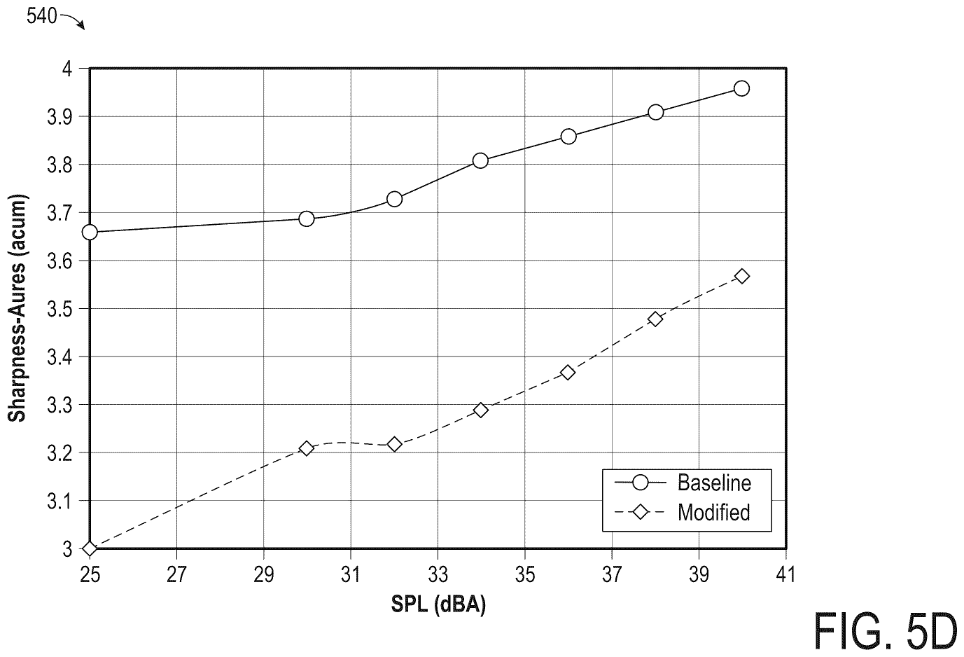

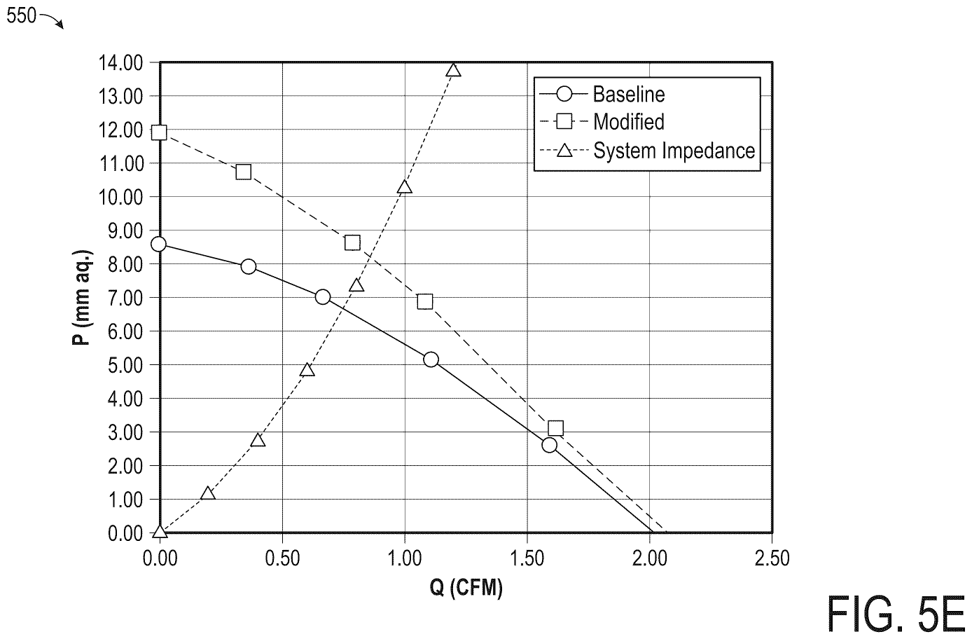

FIGS. 5A-5E illustrate example experimental data showing the benefits of impeller designs of the present disclosure. In particular, the data are related to an example design such as the one shown in FIG. 3, where the thickness of the discs 114A, 114B is about or approximately 5% to 35% of the impeller height (at the tip of the impeller) and the width of the ring in radial direction is between about or approximately 1-50% of the impeller radius. The plot 510 shown in FIG. 5A illustrates a spectral plot for a baseline design, i.e., an impeller without discs, and the impeller design with thin film discs coupled thereto at 5350 rpm. As shown, a significant reduction in A-weighted sound pressure level (SPL[A]) in audible frequency range of 400-10000 Hz can be observed with 6dBA reduction in overall SPL[A] for the modified design compared to baseline.

The plot 520 shown in FIG. 5B illustrates overall SPL vs angular speed for the baseline and modified designs. It will be observed that for the same overall SPL, the modified design can rotate at higher angular speed, indicating a potential of higher fan performance in terms of P-Q characteristics.

The plot 530 shown in FIG. 5C illustrates a P-Q characteristics comparison for the baseline and modified designs at different iso-acoustics level. It will be seen observed that the modified design shows an approximate 10-15% improvement in P-Q characteristics, which may mainly be due to an increase in fan speed at the same overall SPL[A] (due to reduction in vortex shedding from impeller blade edges as discussed above).

The plot 540 shown in FIG. 5D illustrates sharpness (Aures) levels for the baseline and modified designs. It will be observed from this that the modified design shows much improved sharpness levels over the baseline design, providing better user experience.

The plot 550 shown in FIG. 5E illustrates an example system impedance plotted against the P-Q curves for the baseline and modified designs, where the intersection of the system impedance line and a respective P-Q curve indicates operating conditions. As shown, the modified design exhibits a shift to the upper right in the P-Q curve, indicating an increase of flow and TDP improvement.

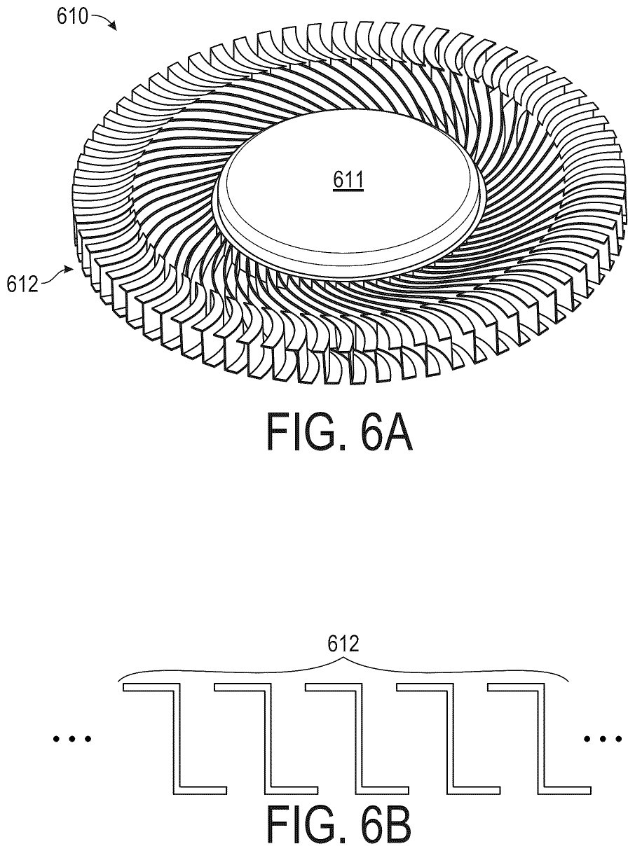

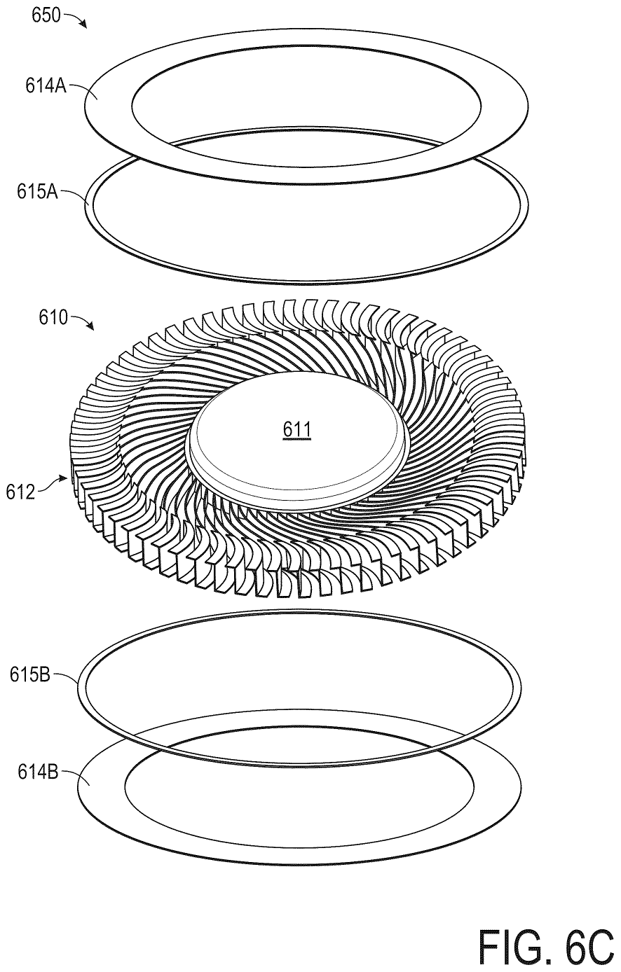

FIGS. 6A-6C illustrate another example modified impeller design in accordance with embodiments of the present disclosure. In particular, FIG. 6A illustrates an impeller 610 with modified impeller blades 612 extending from a central hub 611, FIG. 6B illustrates a side view of the modified impeller blades 612, and FIG. 6C illustrates an exploded view of an impeller design 650 incorporating discs 614A, 614B coupled to opposite sides of the blades 612 of the impeller 610 (via adhesive rings 615A, 615B, respectively). In some cases, the impeller 610 may be implemented in a blower apparatus without the inclusion of discs 614A, 614B and may achieve similar benefits to the above examples. In other cases, the discs 614A, 614B may be adhered to the impeller 610 as shown in FIG. 6C to provide similar or further advantages to the above examples.

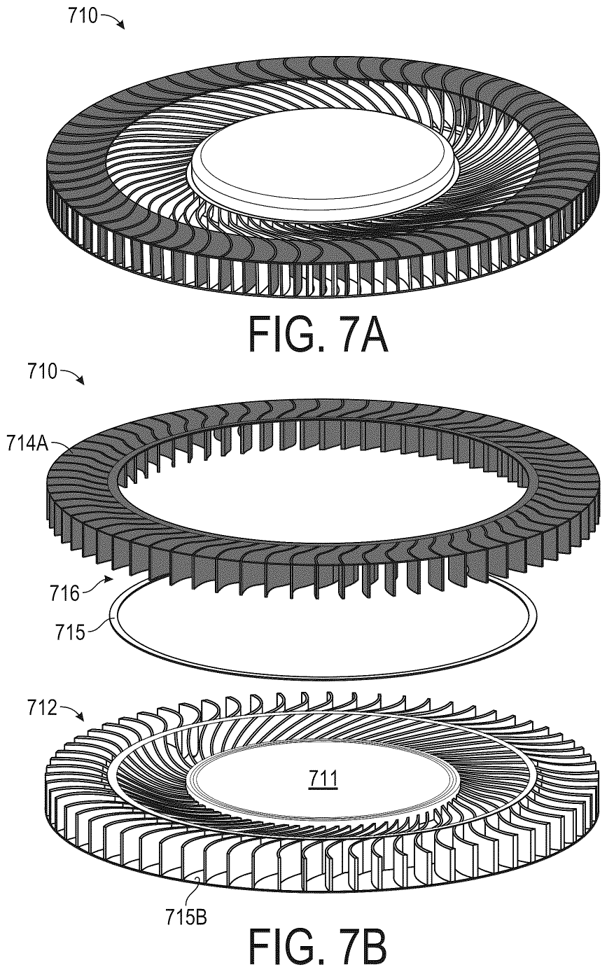

FIGS. 7A-7B illustrate yet another example modified impeller design in accordance with embodiments of the present disclosure. In particular, FIG. 7A illustrates an impeller design 710 that incorporates a disc 714A with blade portions 716 coupled (via an adhesive ring 715) to one side of blades 712 (extending from a central hub 711) and another disc 714B integrated with the opposite side of the blades 712 than the disc 714A. FIG. 7B illustrates an exploded view of the impeller design 710.

FIG. 8 illustrates a computing device 800 incorporating a blower apparatus 810 of the present disclosure. The example computing device 800 includes a device housing 802 in which one or more processors 806 and memory 804 are located. The device 800 further includes a heat exchanger 808 coupled (e.g., thermally coupled) to the processor(s) 806 to remove heat therefrom. The device 800 further includes two blower apparatuses 810A, 810B that are implemented in the same or similar manner as described above, i.e., with annular discs 814A, 814B coupled to or integrated with the impeller blades of the blower apparatuses. The apparatuses 810A, 810B are positioned such that their respective outlets are adjacent to a portion of the heat exchanger 808 (e.g., adjacent to heat pipes of the heat exchanger 808 extending away from the portion of the heat exchanger 808 over the processor(s) 806). In this manner, the blower apparatuses 810A, 810B can blow air across portions of the heat exchanger 808, providing convection cooling to the heat exchanger and accordingly providing additional cooling to the processor(s) 806.

### Example Computing Systems

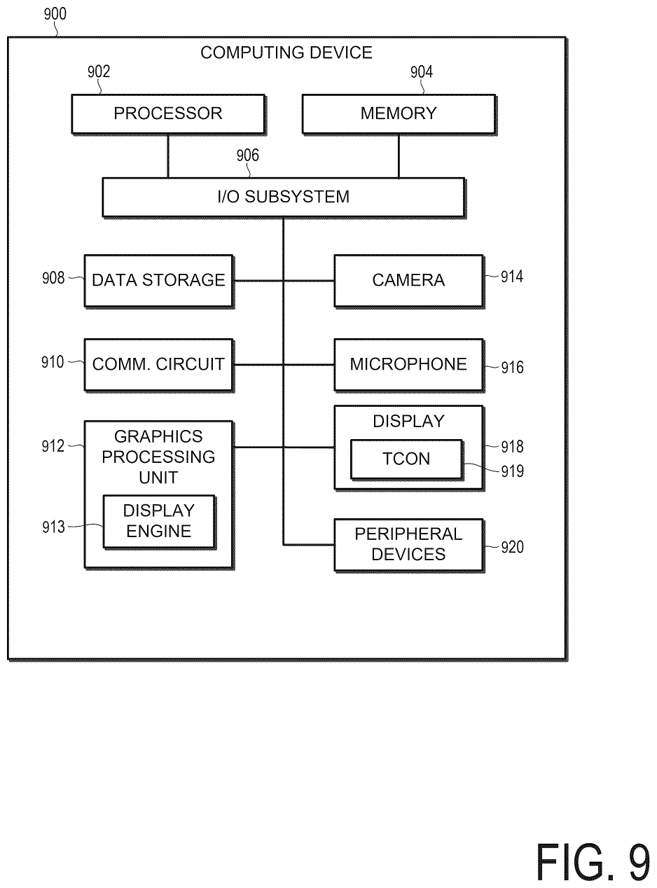

FIG. 9 illustrates a simplified block diagram of a computing device in which aspects of the present disclosure may be incorporated. The computing device 900 for selective updating of a display is shown. In use, the illustrative computing device 900 determines one or more regions of a display to be updated. For example, a user may move a cursor and a clock may change from one frame to the next, requiring an update to two regions of a display. The computing device 900 sends update regions from a source to a sink in the display 918 over a link. In the illustrative embodiment, the source does not have direct access to the link port while the sink does have direct access to the link port. The source can send an indication that a particular update message is the last message to be sent for the current frame, after which the source will be entering an idle period without sending update messages. The sink can then place the link in a low-power state to reduce power usage.

The computing device 900 may be embodied as any type of computing device. For example, the computing device 900 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, and/or any other computing device. In some embodiments, the computing device 900 may be located in a data center, such as an enterprise data center (e.g., a data center owned and operated by a company and typically located on company premises), managed services data center (e.g., a data center managed by a third party on behalf of a company), a co-located data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative computing device 900 includes a processor 902, a memory 904, an input/output (I/O) subsystem 906, data storage 908, a communication circuit 910, a graphics processing unit 912, a camera 914, a microphone 916, a display 918, and one or more peripheral devices 920. In some embodiments, one or more of the illustrative components of the computing device 900 may be incorporated in, or otherwise form a portion of, another component. For example, the memory 904, or portions thereof, may be incorporated in the processor 902 in some embodiments. In some embodiments, one or more of the illustrative components may be physically separated from another component.

The processor 902 may be embodied as any type of processor capable of performing the functions described herein. For example, the processor 902 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 904 may be embodied as any type of volatile or non-volatile memory or data storage capable of performing the functions described herein. In operation, the memory 904 may store various data and software used during operation of the computing device 900 such as operating systems, applications, programs, libraries, and drivers. The memory 904 is communicatively coupled to the processor 902 via the I/O subsystem 906, which may be embodied as circuitry and/or components to facilitate input/output operations with the processor 902, the memory 904, and other components of the computing device 900. For example, the I/O subsystem 906 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 906 may connect various internal and external components of the computing device 900 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 906 may form a portion of a system-on-a-chip (SoC) and be incorporated, along with the processor 902, the memory 904, and other components of the computing device 900 on a single integrated circuit chip.

The data storage 908 may be embodied as any type of device or devices configured for the short-term or long-term storage of data. For example, the data storage 908 may include any one or more memory devices and circuits, memory cards, hard disk drives, solid-state drives, or other data storage devices.

The communication circuit 910 may be embodied as any type of interface capable of interfacing the computing device 900 with other computing devices, such as over one or more wired or wireless connections. In some embodiments, the communication circuit 910 may be capable of interfacing with any appropriate cable type, such as an electrical cable or an optical cable. The communication circuit 910 may be configured to use any one or more communication technology and associated protocols (e.g., Ethernet, Bluetooth®, Wi-Fi®, WiMAX, near field communication (NFC), etc.). The communication circuit 910 may be located on silicon separate from the processor 902, or the communication circuit 910 may be included in a multi-chip package with the processor 902, or even on the same die as the processor 902. The communication circuit 910 may be embodied as one or more add-in-boards, daughtercards, network interface cards, controller chips, chipsets, specialized components such as a field-programmable gate array (FPGA) or application-specific integrated circuit (ASIC), or other devices that may be used by the computing device 900 to connect with another computing device. In some embodiments, communication circuit 910 may be embodied as part of a system-on-a-chip (SoC) that includes one or more processors or included on a multichip package that also contains one or more processors. In some embodiments, the communication circuit 910 may include a local processor (not shown) and/or a local memory (not shown) that are both local to the communication circuit 910. In such embodiments, the local processor of the communication circuit 910 may be capable of performing one or more of the functions of the processor 902 described herein. Additionally or alternatively, in such embodiments, the local memory of the communication circuit 910 may be integrated into one or more components of the computing device 900 at the board level, socket level, chip level, and/or other levels.

The graphics processing unit 912 is configured to perform certain computing tasks, such as video or graphics processing. The graphics processing unit 912 may be embodied as one or more processors, data processing unit, field-programmable gate arrays (FPGAs), application-specific integrated circuits (ASICs), and/or any combination of the above. In some embodiments, the graphics processing unit 912 may send frames or partial update regions to the display 918. For instance, the example graphics processing unit 912 includes a display engine 913, which may be embodied as hardware, firmware, software, virtualized hardware, emulated architecture, and/or a combination thereof, and is configured to determine frames to be sent to the display 918 and send the images to the display 918. In the illustrative embodiment, the display engine 913 is part of the graphics processing unit 912. In other embodiments, the display engine 913 may be part of the processor 902 or other component of the device 900.

In certain embodiments, the display engine 913 may include circuitry to implement aspects of the present disclosure, e.g., circuitry to implement the computational aspects described with respect to FIGS. 1A-1B above. For example, the display engine 913 may access frames stored in the memory 904, enhance the frames as described above, and then stream the frames to the display 918.

The camera 914 may include one or more fixed or adjustable lenses and one or more image sensors. The image sensors may be any suitable type of image sensors, such as a CMOS or CCD image sensor. The camera 914 may have any suitable aperture, focal length, field of view, etc. For example, the camera 914 may have a field of view of 60-110° in the azimuthal and/or elevation directions.

The microphone 916 is configured to sense sound waves and output an electrical signal indicative of the sound waves. In the illustrative embodiment, the computing device 900 may have more than one microphone 916, such as an array of microphones 916 in different positions.

The display 918 may be embodied as any type of display on which information may be displayed to a user of the computing device 900, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, and/or other display technology. The display 918 may have any suitable resolution, such as 7680×4320, 3840×2160, 1920×1200, 1920×1080, etc.

The display 918 includes a timing controller (TCON) 919, which includes circuitry to convert video data received from the graphics processing unit 912 into signals that drive a panel of the display 918. For example, TCON 919 may enhance frames received from the graphics processing unit 912 and stream the frames to the panel of the display 918.

In some embodiments, the computing device 900 may include other or additional components, such as those commonly found in a computing device. For example, the computing device 900 may also have peripheral devices 920, such as a keyboard, a mouse, a speaker, an external storage device, etc. In some embodiments, the computing device 900 may be connected to a dock that can interface with various devices, including peripheral devices 920. In some embodiments, the peripheral devices 920 may include additional sensors that the computing device 500 can use to monitor the video conference, such as a time-of-flight sensor or a millimeter-wave sensor.

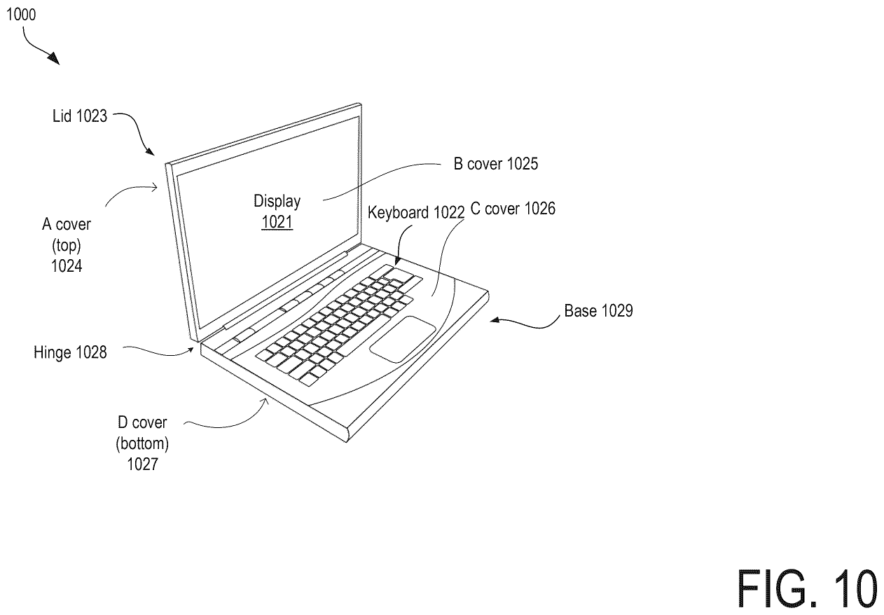

FIG. 10 illustrates an example computing device 1000 in which aspects of the present disclosure may be incorporated. The computing device 1000 can be a laptop (as shown) or another type of mobile computing device with a similar form factor, such as a foldable tablet or smartphone. In some embodiments, embodiments of present disclosure may be incorporated into a free-standing display monitor, which may be connected to a computing device that outputs image data to the display.

The computing device 1000 includes a housing, which includes a lid 1023 with an A cover 1024 that is a “world-facing” surface of the lid 1023 when the computing device 1000 is in a closed configuration and a B cover 1025 that comprises a user-facing display 1021 when the lid 1023 is open (e.g., as shown). The computing device 1000 also includes a base 1029 with a C cover 1026 that includes a keyboard 1022 that is upward facing when the device 1000 is an open configuration (e.g., as shown) and a D cover 1027 that forms the bottom of the base 1029. In some embodiments, the base 1029 includes the primary computing resources (e.g., host processor unit(s), graphics processing unit (GPU)) of the device 1000, along with a battery, memory, and storage, and communicates with the lid 1023 via wires that pass through a hinge 1028 that connects the base 1029 with the lid 1023. In some embodiments, the computing device 1000 can be a dual display device with a second display comprising a portion of the C cover 1026. For example, in some embodiments, an “always-on” display (AOD) can occupy a region of the C cover below the keyboard that is visible when the lid 1023 is closed. In other embodiments, a second display covers most of the surface of the C cover and a removable keyboard can be placed over the second display or the second display can present a virtual keyboard to allow for keyboard input.

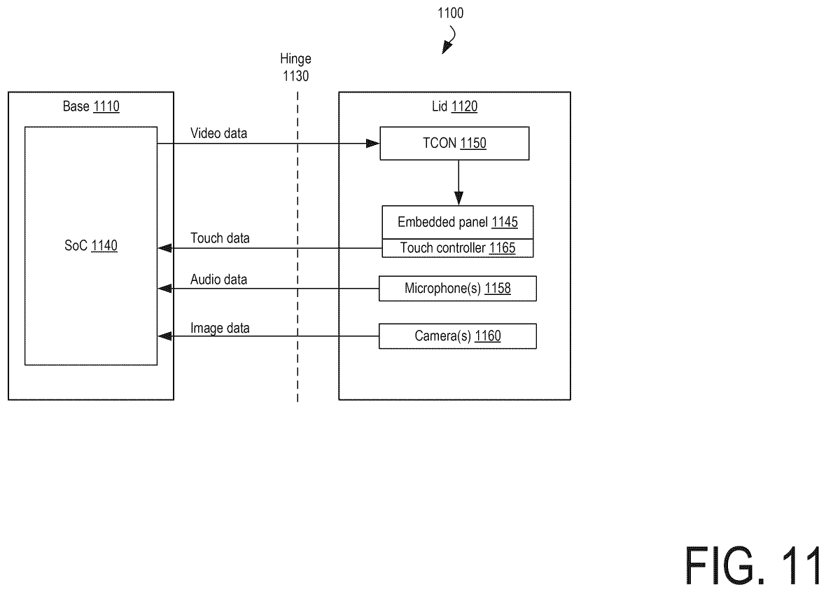

FIG. 11 illustrates an example block diagram of a computing device in which aspects of the present disclosure may be incorporated. The computing device 1100 comprises a base 1110 connected to a lid 1120 by a hinge 1130. The mobile computing device (also referred to herein as “user device”) 1100 can be a laptop or a mobile computing device with a similar form factor. The base 1110 comprises a host system-on-a-chip (SoC) 1140 that comprises one or more processor units integrated with one or more additional components, such as a memory controller, graphics processing unit (GPU), caches, an image processing module, and other components described herein. For example, the SoC 1140 may include one or more of the processor 902, memory 904, I/O subsystem 906, and graphics processing unit 912 of FIG. 9. The base 1110 can further comprise a physical keyboard, touchpad, battery, memory, storage, and external ports. The lid 1120 comprises an embedded display panel 1145, a timing controller (TCON) 1150, one or more microphones 1158, one or more cameras 1160, and a touch controller 1165. The TCON 1150 converts video data 1190 received from the SoC 1140 into signals that drive the display panel 1145.

The display panel 1145 can be any type of embedded display in which the display elements responsible for generating light or allowing the transmission of light are located in each pixel. Such displays may include TFT LCD (thin-film-transistor liquid crystal display), micro-LED (micro-light-emitting diode (LED)), OLED (organic LED), and QLED (quantum dot LED) displays. The display panel 1145 can comprise a touchscreen comprising one or more dedicated layers for implementing touch capabilities or ‘in-cell’ or ‘on-cell’ touchscreen technologies that do not require dedicated touchscreen layers. A touch controller 1165 drives touchscreen technology utilized in the display panel 1145 and collects touch sensor data provided by the employed touchscreen technology. The microphones 1158 can comprise microphones located in the bezel of the lid or in-display microphones located in the display area, the region of the panel that displays content. The one or more cameras 1160 can similarly comprise cameras located in the bezel or in-display cameras located in the display area.

The hinge 1130 can be any physical hinge that allows the base 1110 and the lid 1120 to be rotatably connected. The wires that pass across the hinge 1130 comprise wires for passing video data from the SoC 1140 to the TCON 1150, wires for passing audio data between the microphones 1158 and the SoC 1140, wires for providing image data from the cameras 1160 to the SoC 1140, and wires for providing touch data from the touch controller 1165 to the SoC 1140. In some embodiments, data shown as being passed over different sets of wires between the SoC and various components are communicated over the same set of wires. For example, in some embodiments, all of the different types of data shown can be sent over a single PCIe-based or USB-based data bus. In some embodiments, the lid 1120 is removably attachable to the base 1110. In some embodiments, the hinge can allow the base 1110 and the lid 1120 to rotate to substantially 360 degrees with respect to each other.

The components illustrated in FIG. 11 as being located in the base of a mobile computing device can be located in a base housing (e.g., base 1029 of the device 1000) and components illustrated in FIG. 11 as being located in the lid of a mobile computing device can be located in a lid housing (e.g., lid 1023 of the device 1000).

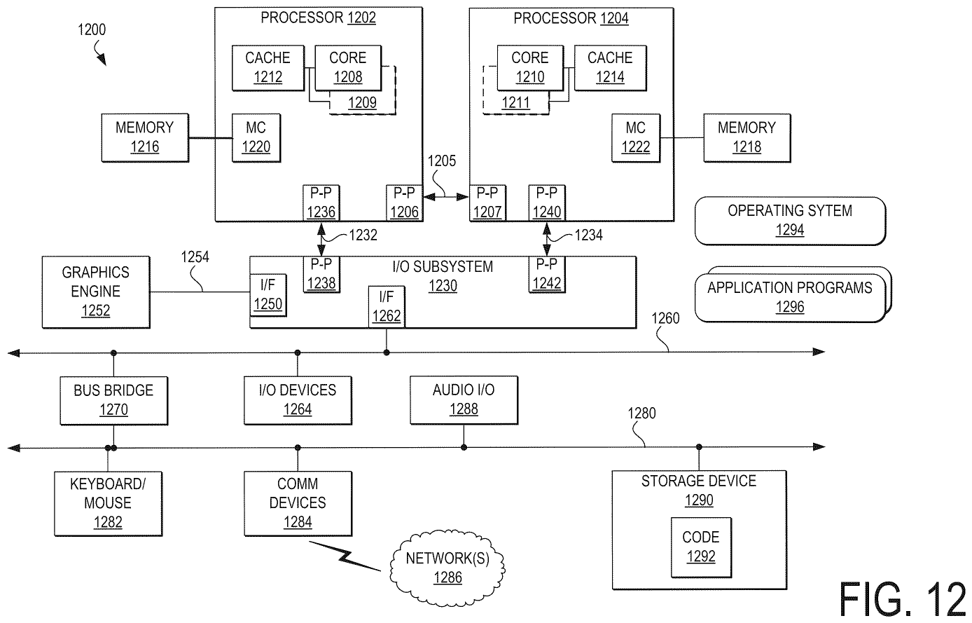

FIG. 12 is a block diagram of computing device components which may be included in a mobile computing device incorporating aspects of the present disclosure. In some embodiments, the components shown may be implemented within the SoC 1140 of FIG. 11, for instance. Generally, components shown in FIG. 12 can communicate with other shown components, although not all connections are shown, for ease of illustration. The components 1200 comprise a multiprocessor system comprising a first processor 1202 and a second processor 1204 and is illustrated as comprising point-to-point (P-P) interconnects. For example, a point-to-point (P-P) interface 1206 of the processor 1202 is coupled to a point-to-point interface 1207 of the processor 1204 via a point-to-point interconnection 1205. It is to be understood that any or all of the point-to-point interconnects illustrated in FIG. 12 can be alternatively implemented as a multi-drop bus, and that any or all buses illustrated in FIG. 12 could be replaced by point-to-point interconnects.

As shown in FIG. 12, the processors 1202 and 1204 are multicore processors. Processor 1202 comprises processor cores 1208 and 1209, and processor 1204 comprises processor cores 1210 and 1211. Processor cores 1208-1211 can execute computer-executable instructions in a manner similar to that discussed below in connection with FIG. 9, or in other manners. Processors 1202 and 1204 further comprise at least one shared cache 1212 and 1214, respectively. The shared caches 1212 and 1214 can store data (e.g., instructions) utilized by one or more components of the processor, such as the processor cores 1208-1209 and 1210-1211. The shared caches 1212 and 1214 can be part of a memory hierarchy for the device. For example, the shared cache 1212 can locally store data that is also stored in a memory 1216 to allow for faster access to the data by components of the processor 1202. In some embodiments, the shared caches 1212 and 1214 can comprise multiple cache layers, such as level 1 (L1), level 2 (L2), level 3 (L3), level 4 (L4), and/or other caches or cache layers, such as a last level cache (LLC).

Although two processors are shown, the device can comprise any number of processors or other compute resources. Further, a processor can comprise any number of processor cores. A processor can take various forms such as a central processing unit, a controller, a graphics processor, an accelerator (such as a graphics accelerator, digital signal processor (DSP), or artificial intelligence (AI) accelerator)). A processor in a device can be the same as or different from other processors in the device. In some embodiments, the device can comprise one or more processors that are heterogeneous or asymmetric to a first processor, accelerator, field programmable gate array (FPGA), or any other processor. There can be a variety of differences between the processing elements in a system in terms of a spectrum of metrics of merit including architectural, microarchitectural, thermal, power consumption characteristics and the like. These differences can effectively manifest themselves as asymmetry and heterogeneity amongst the processors in a system. In some embodiments, the processors 1202 and 1204 reside in a multi-chip package. As used herein, the terms “processor unit” and “processing unit” can refer to any processor, processor core, component, module, engine, circuitry or any other processing element described herein. A processor unit or processing unit can be implemented in hardware, software, firmware, or any combination thereof capable of.

Processors 1202 and 1204 further comprise memory controller logic (MC) 1220 and 1222. As shown in FIG. 12, MCs 1220 and 1222 control memories 1216 and 1218 coupled to the processors 1202 and 1204, respectively. The memories 1216 and 1218 can comprise various types of memories, such as volatile memory (e.g., dynamic random-access memories (DRAM), static random-access memory (SRAM)) or non-volatile memory (e.g., flash memory, solid-state drives, chalcogenide-based phase-change non-volatile memories). While MCs 1220 and 1222 are illustrated as being integrated into the processors 1202 and 1204, in alternative embodiments, the MCs can be logic external to a processor, and can comprise one or more layers of a memory hierarchy.

Processors 1202 and 1204 are coupled to an Input/Output (I/O) subsystem 1230 via P-P interconnections 1232 and 1234. The point-to-point interconnection 1232 connects a point-to-point interface 1236 of the processor 1202 with a point-to-point interface 1238 of the I/O subsystem 1230, and the point-to-point interconnection 1234 connects a point-to-point interface 1240 of the processor 1204 with a point-to-point interface 1242 of the I/O subsystem 1230. Input/Output subsystem 1230 further includes an interface 1250 to couple I/O subsystem 1230 to a graphics module 1252, which can be a high-performance graphics module. The I/O subsystem 1230 and the graphics module 1252 are coupled via a bus 1254. Alternately, the bus 1254 could be a point-to-point interconnection.

Input/Output subsystem 1230 is further coupled to a first bus 1260 via an interface 1262. The first bus 1260 can be a Peripheral Component Interconnect (PCI) bus, a PCI Express (PCIe) bus, another third generation I/O (input/output) interconnection bus or any other type of bus.

Various I/O devices 1264 can be coupled to the first bus 1260. A bus bridge 1270 can couple the first bus 1260 to a second bus 1280. In some embodiments, the second bus 1280 can be a low pin count (LPC) bus. Various devices can be coupled to the second bus 1280 including, for example, a keyboard/mouse 1282, audio I/O devices 1288 and a storage device 1290, such as a hard disk drive, solid-state drive or other storage device for storing computer-executable instructions (code) 1292. The code 1292 can comprise computer-executable instructions for performing technologies described herein. Additional components that can be coupled to the second bus 1280 include communication device(s) or components 1284, which can provide for communication between the device and one or more wired or wireless networks 1286 (e.g. Wi-Fi, cellular or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

The device can comprise removable memory such as flash memory cards (e.g., SD (Secure Digital) cards), memory sticks, Subscriber Identity Module (SIM) cards). The memory in the computing device (including caches 1212 and 1214, memories 1216 and 1218 and storage device 1290) can store data and/or computer-executable instructions for executing an operating system 1294, or application programs 1296. Example data includes web pages, text messages, images, sound files, video data, sensor data, or other data sets to be sent to and/or received from one or more network servers or other devices by the device via one or more wired or wireless networks, or for use by the device. The device can also have access to external memory (not shown) such as external hard drives or cloud-based storage.

The operating system 1294 can control the allocation and usage of the components illustrated in FIG. 12 and support one or more application programs 1296. The application programs 1296 can include common mobile computing device applications (e.g., email applications, calendars, contact managers, web browsers, messaging applications) as well as other computing applications.

The device can support various input devices, such as a touchscreen, microphones, cameras (monoscopic or stereoscopic), trackball, touchpad, trackpad, mouse, keyboard, proximity sensor, light sensor, pressure sensor, infrared sensor, electrocardiogram (ECG) sensor, PPG (photoplethysmogram) sensor, galvanic skin response sensor, and one or more output devices, such as one or more speakers or displays. Any of the input or output devices can be internal to, external to or removably attachable with the device. External input and output devices can communicate with the device via wired or wireless connections.

In addition, the computing device can provide one or more natural user interfaces (NUIs). For example, the operating system 1294 or application programs 1296 can comprise speech recognition as part of a voice user interface that allows a user to operate the device via voice commands. Further, the device can comprise input devices and components that allows a user to interact with the device via body, hand, or face gestures.

The device can further comprise one or more communication components 1284. The components 1284 can comprise wireless communication components coupled to one or more antennas to support communication between the device and external devices. Antennas can be located in a base, lid, or other portion of the device. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM). In addition, the wireless modems can support communication with one or more cellular networks for data and voice communications within a single cellular network, between cellular networks, or between the mobile computing device and a public switched telephone network (PSTN).

The device can further include at least one input/output port (which can be, for example, a USB, IEEE 1394 (FireWire), Ethernet and/or RS-232 port) comprising physical connectors; a power supply (such as a rechargeable battery); a satellite navigation system receiver, such as a GPS receiver; a gyroscope; an accelerometer; and a compass. A GPS receiver can be coupled to a GPS antenna. The device can further include one or more additional antennas coupled to one or more additional receivers, transmitters and/or transceivers to enable additional functions.

FIG. 12 illustrates one example computing device architecture. Computing devices based on alternative architectures can be used to implement technologies described herein. For example, instead of the processors 1202 and 1204, and the graphics module 1252 being located on discrete integrated circuits, a computing device can comprise a SoC (system-on-a-chip) integrated circuit incorporating one or more of the components illustrated in FIG. 12. In one example, an SoC can comprise multiple processor cores, cache memory, a display driver, a GPU, multiple I/O controllers, an AI accelerator, an image processing unit driver, I/O controllers, an AI accelerator, an image processor unit. Further, a computing device can connect elements via bus or point-to-point configurations different from that shown in FIG. 12. Moreover, the illustrated components in FIG. 12 are not required or all-inclusive, as shown components can be removed and other components added in alternative embodiments.

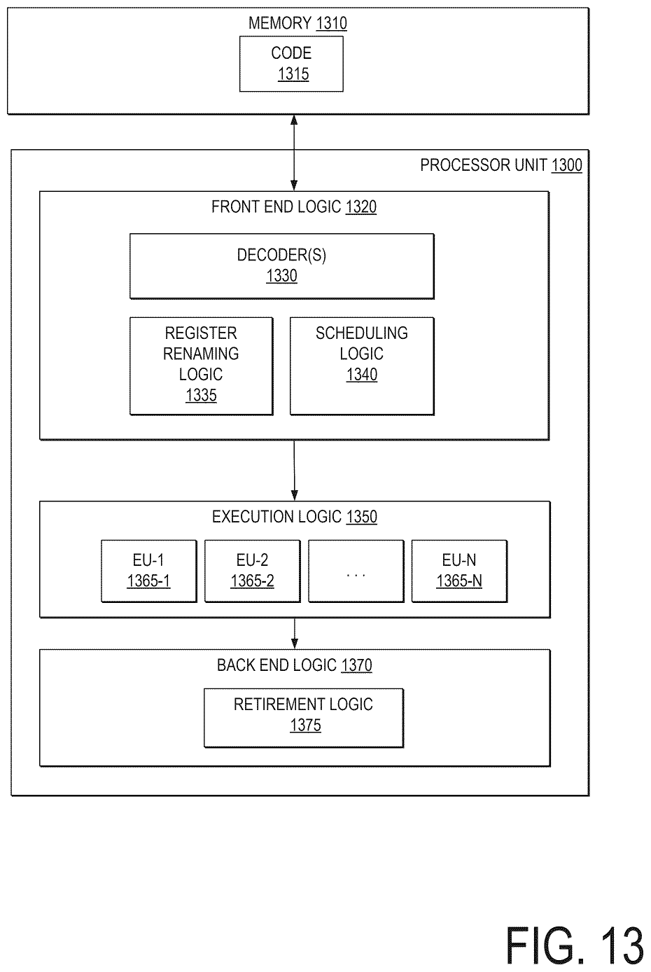

FIG. 13 is a block diagram of an example processor unit 1300 to execute computer-executable instructions. The processor unit 1300 can be any type of processor or processor core, such as a microprocessor, an embedded processor, a digital signal processor (DSP), network processor, or accelerator. The processor unit 1300 can be a single-threaded core or a multithreaded core in that it may include more than one hardware thread context (or “logical processor”) per core.

FIG. 13 also illustrates a memory 1310 coupled to the processor unit 1300. The memory 1310 can be any memory described herein or any other memory known to those of skill in the art. The memory 1310 can store computer-executable instructions 1315 (code) executable by the processor unit 1300.

The processor core comprises front-end logic 1320 that receives instructions from the memory 1310. An instruction can be processed by one or more decoders 1330. The decoder 1330 can generate as its output a micro operation such as a fixed width micro operation in a predefined format, or generate other instructions, microinstructions, or control signals, which reflect the original code instruction. The front-end logic 1320 further comprises register renaming logic 1335 and scheduling logic 1340, which generally allocate resources and queues operations corresponding to converting an instruction for execution.

The processor unit 1300 further comprises execution logic 1350, which comprises one or more execution units (EUs) 1365-1 through 1365-N. Some processor core embodiments can include a number of execution units dedicated to specific functions or sets of functions. Other embodiments can include only one execution unit or one execution unit that can perform a particular function. The execution logic 1350 performs the operations specified by code instructions. After completion of execution of the operations specified by the code instructions, back end logic 1370 retires instructions using retirement logic 1375. In some embodiments, the processor unit 1300 allows out of order execution but requires in-order retirement of instructions. Retirement logic 1375 can take a variety of forms as known to those of skill in the art (e.g., re-order buffers or the like).

The processor unit 1300 is transformed during execution of instructions, at least in terms of the output generated by the decoder 1330, hardware registers and tables utilized by the register renaming logic 1335, and any registers (not shown) modified by the execution logic 1350. Although not illustrated in FIG. 13, a processor can include other elements on an integrated chip with the processor unit 1300. For example, a processor may include additional elements such as memory control logic, one or more graphics modules, I/O control logic modules and/or one or more caches.

As used in any embodiment herein, the term “module” refers to logic that may be implemented in a hardware component or device, software or firmware running on a processor, or a combination thereof, to perform one or more operations consistent with the present disclosure. Software may be embodied as a software package, code, instructions, instruction sets and/or data recorded on non-transitory computer-readable storage mediums. Firmware may be embodied as code, instructions or instruction sets and/or data that are hard-coded (e.g., nonvolatile) in memory devices. As used in any embodiment herein, the term “circuitry” can comprise, for example, singly or in any combination, hardwired circuitry, programmable circuitry such as computer processors comprising one or more individual instruction processing cores, state machine circuitry, and/or firmware that stores instructions executed by programmable circuitry. Modules described herein may, collectively or individually, be embodied as circuitry that forms a part of one or more devices. Thus, any of the modules can be implemented as circuitry, such as continuous itemset generation circuitry, entropy-based discretization circuitry, etc. A computer device referred to as being programmed to perform a method can be programmed to perform the method via software, hardware, firmware or combinations thereof.

The use of reference numbers in the claims and the specification is meant as in aid in understanding the claims and the specification and is not meant to be limiting.

Any of the disclosed methods can be implemented as computer-executable instructions or a computer program product. Such instructions can cause a computer or one or more processors capable of executing computer-executable instructions to perform any of the disclosed methods. Generally, as used herein, the term “computer” refers to any computing device or system described or mentioned herein, or any other computing device. Thus, the term “computer-executable instruction” refers to instructions that can be executed by any computing device described or mentioned herein, or any other computing device.

The computer-executable instructions or computer program products as well as any data created and used during implementation of the disclosed technologies can be stored on one or more tangible or non-transitory computer-readable storage media, such as optical media discs (e.g., DVDs, CDs), volatile memory components (e.g., DRAM, SRAM), or non-volatile memory components (e.g., flash memory, solid state drives, chalcogenide-based phase-change non-volatile memories). Computer-readable storage media can be contained in computer-readable storage devices such as solid-state drives, USB flash drives, and memory modules. Alternatively, the computer-executable instructions may be performed by specific hardware components that contain hardwired logic for performing all or a portion of disclosed methods, or by any combination of computer-readable storage media and hardware components.

The computer-executable instructions can be part of, for example, a dedicated software application or a software application that is accessed via a web browser or other software application (such as a remote computing application). Such software can be read and executed by, for example, a single computing device or in a network environment using one or more networked computers. Further, it is to be understood that the disclosed technology is not limited to any specific computer language or program. For instance, the disclosed technologies can be implemented by software written in C++, Java, Perl, Python, JavaScript, Adobe Flash, or any other suitable programming language. Likewise, the disclosed technologies are not limited to any particular computer or type of hardware.

Furthermore, any of the software-based embodiments (comprising, for example, computer-executable instructions for causing a computer to perform any of the disclosed methods) can be uploaded, downloaded or remotely accessed through a suitable communication means. Such suitable communication means include, for example, the Internet, the World Wide Web, an intranet, cable (including fiber optic cable), magnetic communications, electromagnetic communications (including RF, microwave, and infrared communications), electronic communications, or other such communication means.

As used in this application and in the claims, a list of items joined by the term “and/or” can mean any combination of the listed items. For example, the phrase “A, B and/or C” can mean A; B; C; A and B; A and C; B and C; or A, B, and C. Further, as used in this application and in the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

Certain non-limiting examples of the presently described techniques are provided below. Each of the following non-limiting examples may stand on its own or may be combined in any permutation or combination with any one or more of the other examples provided below or throughout the present disclosure.

Example 1 is an apparatus comprising: a housing defining at least one inlet opening and at least one outlet opening; an impeller within the housing, the impeller comprising a plurality of blades extending from a central hub; and at least one annular disc coupled to the plurality of blades.

Example 2 includes the apparatus of Example 1, wherein the annular disc is positioned over between about 1% to about 50% of a radial dimension of the plurality of blades or a thickness of the disc is between about 5% to about 35% of the impeller height at the end of the impeller blades.

Example 3 includes the apparatus of Example 1 or 2, wherein the annular disc is approximately orthogonal to the plurality of blades.

Example 4 includes the apparatus of Example 1, wherein the apparatus comprises a first annular disc coupled to a first side of the plurality of blades and a second annular disc on a second side of the plurality of blades opposite the first side.

Example 5 includes the apparatus of Example 4, wherein the second annular disc is coupled to the second side of the plurality of blades.

Example 6 includes the apparatus of Example 4, wherein the second annular disc is integrated with the plurality of blades.

Example 7 includes the apparatus of any one of Examples 4-6, wherein a radial dimension of the first annular disc is approximately equal to a radial dimension of the second annular disc.

Example 8 includes the apparatus of any one of Examples 4-6, wherein the first annular disc has at least one dimension that is different from the second annular disc.

Example 9 includes the apparatus of any one of Examples 1-8, wherein the annular disc comprises a plurality of fins extending therefrom, each of the plurality of fins disposed between a respective pair of blades of the impeller.

Example 10 includes the apparatus of any one of Examples 1-8, wherein each blade comprises a body portion and surfaces extending approximately orthogonally from the body portion.

Example 11 includes the apparatus of any one of Examples 1-10, further comprising a processor and a heat exchanger coupled to the processor, wherein the at least one outlet opening is disposed adjacent to a portion of the heat exchanger.

Example 12 is an apparatus comprising: a housing defining at least one inlet opening and at least one outlet opening; an impeller within the housing, the impeller comprising a plurality of blades extending from a central hub, wherein each blade comprises a body portion and surfaces extending approximately orthogonally from the body portion.

Example 13 includes the apparatus of Example 12, wherein the surfaces extending from the body portion of each blade comprise a first surface extending in a first direction and a second surface extending in a second direction opposite the first direction.

Example 14 includes the apparatus of Example 13, wherein the first surface extends from a first side of the body portion and the second surface extends from a second side of the body portion opposite the first side.

Example 15 includes the apparatus of any one of Examples 12-14, wherein the surfaces are at a distal end of the plurality of blades with respect to the central hub.

Example 16 includes the apparatus of any one of Examples 12-15, further comprising at least one annular disc coupled to the plurality of blades.

Example 17 includes the apparatus of Example 16, wherein the at least one annular disc is positioned over between about 1% to about 50% of a radial dimension of the plurality of blades.

Example 18 is a device comprising: a device housing; and a blower apparatus according to any one of Examples 1-17.

Example 19 includes the device of Example 18, further comprising a processor and memory.

Example 20 includes the device of Example 18, wherein the device housing comprises a base portion and a lid portion.

Example 21 is a system comprising: memory; a processor; a heat exchanger coupled to the processor; and a blower apparatus according to any one of Examples 1-17.

Example 22 includes the system of Example 21, wherein the system comprises a laptop computer, the laptop computer comprising a base portion and a lid portion, the heat exchange apparatus within the base portion of the laptop computer.

1. An apparatus comprising:
a housing defining at least one inlet opening and at least one outlet opening;
an impeller within the housing, the impeller comprising a plurality of blades extending from a central hub; and
an annular disc coupled to the plurality of blades.

2. The apparatus of claim 1, wherein the annular disc is positioned over between about 1% to about 50% of a radial dimension of the plurality of blades.

3. The apparatus of claim 1, wherein the annular disc is approximately orthogonal to the plurality of blades.

4. The apparatus of claim 1, wherein the apparatus comprises a first annular disc coupled to a first side of the plurality of blades and a second annular disc coupled to a second side of the plurality of blades opposite the first side.

5. The apparatus of claim 4, wherein the second annular disc is integrated with the plurality of blades.

6. The apparatus of claim 4, wherein a radial dimension of the first annular disc is approximately equal to a radial dimension of the second annular disc.

7. The apparatus of claim 4, wherein the first annular disc has at least one dimension that is different from the second annular disc.

8. The apparatus of claim 1, wherein the annular disc comprises a plurality of fins extending therefrom, each of the plurality of fins disposed between a respective pair of blades of the impeller.

9. The apparatus of claim 1, wherein each blade comprises a body portion and surfaces extending approximately orthogonally from the body portion.

10. The apparatus of claim 1, further comprising a processor and a heat exchanger coupled to the processor, wherein the at least one outlet opening is disposed adjacent to a portion of the heat exchanger.

11. An apparatus comprising:
a housing defining at least one inlet opening and at least one outlet opening;
an impeller within the housing, the impeller comprising a plurality of blades extending from a central hub, wherein each blade comprises a body portion and surfaces extending approximately orthogonally from the body portion.

12. The apparatus of claim 11, wherein the surfaces extending from the body portion comprise a first surface extending in a first direction and a second surface extending in a second direction opposite the first direction.

13. The apparatus of claim 12, wherein the first surface extends from a first side of the body portion and the second surface extends from a second side of the body portion opposite the first side.

14. The apparatus of claim 11, wherein the surfaces are at a distal end of the plurality of blades with respect to the central hub.

15. The apparatus of claim 11, further comprising at least one annular disc coupled to the plurality of blades.

16. The apparatus of claim 15, wherein the at least one annular disc is positioned over between about 1% to about 50% of a radial dimension of the plurality of blades.

17. A device comprising:
a device housing; and
a blower apparatus comprising:
an impeller within a housing, the impeller comprising a plurality of blades extending from a central hub; and
an annular disc coupled to the plurality of blades.

18. The device of claim 17, wherein the annular disc is positioned over between about 1 to about 50% of a radial dimension of the plurality of blades.

19. The device of claim 17, wherein the blower apparatus comprises a first annular disc coupled to a first side of the plurality of blades and a second annular disc on a second side of the plurality of blades opposite the first side.

20. The device of claim 17, wherein the device housing comprises a base portion and a lid portion, and the device further comprises a processor and memory.
